(19) United States
(12) Patent Application Publication
(10) Pub. No.: US 2025/0327174 A1
(43) Pub. Date: Oct. 23, 2025

(54) GAS INJECTION SYSTEMS FOR SUPPLYING GAS INTO A REACTION CHAMBER AND SEMICONDUCTOR PROCESSING SYSTEM INCLUDING GAS INJECTION SYSTEMS

(71) Applicant: ASM IP Holding B. V., Almere (NL)

(72) Inventors: Brendan Marozas, Leuven (BE); Rami Khazaka, Leuven (BE); Kishor Patil, Chandler, AZ (US); Krishnaswamy Mahadevan, Tempe, AZ (US); Fan Gao, Chandler, AZ (US); Jing Yuan, Phoenix, AZ (US)

(21) Appl. No.: 19/182,343

(22) Filed: Apr. 17, 2025

Related U.S. Application Data
(60) Provisional application No. 63/636,190, filed on Apr. 19, 2024.

(51) Int. Cl. C23C 16/44; C23C 16/52

(52) U.S. Cl. CPC C23C 16/4405; C23C 16/52

(57) ABSTRACT

Gas injection systems and semiconductor processing systems including such gas injection systems are disclosed. The gas injection systems disclosed include an injector housing having a first series of injection ports and a separate second series of injection ports which are constructed and arranged to reduce parasitic deposition on the inner surfaces of a reaction chamber. Methods for forming silicon-containing layers within a reaction chamber with reduce parasitic deposition on the inner surface of a reaction chamber are also disclosed.

### CROSS-REFERENCE TO RELATED APPLICATION(S)

This application claims the benefit of U.S. Provisional Application 63/636,190 filed on Apr. 19, 2024, the entire contents of which are incorporated herein by reference.

### FIELD

The present disclosure relates generally to the field of systems and apparatus employed in the manufacture of semiconductor devices and integrated circuits. More particular, the present disclosure relates to gas injection systems and associated semiconductor processing systems configured for reducing parasitic deposition within a reaction chamber.

### BACKGROUND

Semiconductor devices can be manufactured in a semiconductor processing system including one or more reaction chambers. Deposition gases, including precursors, dopants, and the like, can be injected into the reaction chamber to form a silicon-containing layer on a substrate disposed within the reaction chamber. In addition, further gases, such as etchants, can also be injected into the reaction chamber during the formation of the silicon-containing layer. For example, etchants can be employed in deposition-etch type processes, and/or in processes for cleaning the inner walls of the reaction chamber in which deposition occurs.

Conventional gas injection systems employed in the injection of precursor gases and etchant gases into a reaction chamber can result in parasitic deposition of an undesirable material on the inner surfaces of the reaction chamber. Such parasitic deposition can negatively impact the quality of the deposited silicon-containing layer, as well as the operation and lifetime of the semiconductor processing system. Accordingly, improved gas injection systems and associated semiconductor processing systems are desirable for reducing, or preventing, parasitic deposition in reaction chambers.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to gas injection systems, semiconductor processing systems including such gas injection systems, and methods for forming silicon-containing layers within a reaction chamber with reduced parasitic deposition on the inner surfaces of the reaction.

In accordance with examples of the disclosure, a gas injection system for supplying a gas into a reaction chamber is provided. In such examples, the gas injection system includes an injector housing including a front face and a rear face, a substrate channel extending through the injector housing from the front face to the rear face, a first series of injection ports disposed in the front face of the injector housing, where the first series of injection ports are positioned above the substrate channel and are in fluid communication with a first manifold, the first manifold includes a plurality of first flow controllers configured to control a flow of a precursor gas from a precursor source to the first series of injection ports, and a second series of injection ports disposed in the front face of the injector housing, where the second series of injection ports are positioned above the first series of injection ports and are in fluid communication with a second manifold, the second manifold includes a plurality of second flow controllers configured to control a flow of a non-precursor gas from a non-precursor source to the second series of injection ports. The gas injection system may also include where the first series of injection ports includes a first plurality of injection ports which are commonly aligned to each other. The gas injection system may also include where the each of the first series of injection ports corresponds one-to-one with each of the plurality of first flow controllers, and each of the second series of injection ports correspond one-to one with each of the plurality of second flow controllers. The gas injection system may also include where the precursor source includes a silicon precursor including at least one of disilane (Si₂H₆), trisilane (Si₃H₈), tetrasilane (Si₄H₁₀), and neopentasilane (Si₅H₁₂). The gas injection system may also include where the non-precursor source includes at least an etchant source includes a halide etchant. Other technical features may be readily apparent to one skilled in the art from the following figures, descriptions, and claims. The gas injection system may also include where each of the second series of injection ports includes a second plurality of injection ports commonly aligned to each other. The gas injection system may also include where the first series of injection ports are orientated parallel to the second series of injection ports. The gas injection system may also include further includes a groove disposed in the front face of the injector housing, the groove surrounding the substrate channel, where the second series of injection ports are positioned between the first series of injection ports and an upper surface of the groove. The gas injection system may also include further includes a third series of injection ports positioned between the substrate channel and a lower surface of the groove, where the third series of injection ports are in fluid communication with the second manifold includes the plurality of second flow controllers configured to control the flow of the non-precursor gas from the non-precursor source to the third series of injection ports. Other technical features may be readily apparent to one skilled in the art from the following figures, descriptions, and claims.

In accordance with examples of the disclosure a semiconductor processing system is provided. The semiconductor processing system includes a reaction chamber which includes an upper inner surface and a lower inner surface, a support assembly for supporting a substrate within the reaction chamber, and a gas injection system for supplying gas into the reaction chamber, the gas injection system includes, an injector housing including a front face and a rear face, a substrate channel extending through the injector housing from the front face to the rear face, a first series of injection ports disposed in the front face of the injector housing, where the first series of injection ports are positioned above the substrate channel and are in fluid communication with a first manifold includes a plurality of first flow controllers configured to control a flow of a precursor gas from a precursor source to the first series of injection ports, and a second series of injection ports disposed in the front face of the injector housing, where the second series of injection ports are positioned between the first series of injection ports and the upper inner surface of the reaction chamber and are in fluid communication with a second manifold includes a plurality of second flow controllers configured to control a flow of a non-precursor gas from a non-precursor source to the second series of injection ports, and an exhaust source positioned downstream of the gas injection system. The semiconductor processing system may also include where the first series of injection ports includes a first plurality of injection ports which are commonly aligned to each other. The semiconductor processing system may also include where the each of the first series of injection ports correspond one-to-one with each of the plurality of first flow controllers, and each of the second series of injection ports correspond one-to one with each of the plurality of second flow controllers. The semiconductor processing system may also include where precursor source includes a silicon precursor including at least one of disilane (Si₂H₆), trisilane (Si₃H₈), tetrasilane (Si₄H₁₀), and neopentasilane (Si₅H₁₂). Other technical features may be readily apparent to one skilled in the art from the following figures, descriptions, and claims. The semiconductor processing system may also include where the second series of injection ports include a second plurality of injection ports which are commonly aligned to each other. The semiconductor processing system may also include where the first series of injection ports is parallel to the second series of injection ports. The semiconductor processing system may also include further includes a groove disposed in the front face of the injector housing, the groove surrounding the substrate channel, where the second series of injection ports are positioned between the first series of injection ports and an upper surface of the groove. The semiconductor processing system may also include further includes a third series of injection ports disposed in the front face of the injector housing and positioned between the substrate channel and a lower surface of the groove, where the third series of injection ports are in fluid communication with the second manifold includes the plurality of second flow controllers configured to control the flow of the non-precursor gas from the non-precursor source to the third series of injection ports. Other technical features may be readily apparent to one skilled in the art from the following figures, descriptions, and claims.

In accordance with examples of the disclosure a method for forming a silicon-containing layer within a reaction chamber including an upper inner surface and a lower inner surface is provided. The method includes introducing a substrate into the reaction chamber through a substrate channel extending through a injector housing of a gas injection system, and seating the substrate on a support assembly, injecting a precursor gas into the reaction chamber through a first series of injection ports disposed in a front face of the injector housing, and injecting a non-precursor gas into the reaction chamber through a second series of injection ports disposed in the front face of the injector housing above the first series of injection ports, where the non-precursor gas forms a gas curtain between the precursor gas and the upper inners surface of the reaction chamber thereby reducing parasitic deposition on the upper inner surface. The method may also include further includes injecting an addition non-precursor gas into the reaction chamber through a third series of injection ports disposed in the front face of the injector housing below the substrate channel, where the additional non-precursor gas forms an additional gas curtain between the precursor gas and the lower inner surface of the reaction chamber thereby reducing parasitic deposition on the lower inner surface. The method may also include where the precursor gas includes at least one of disilane (Si₂H₆), trisilane (Si₃H₈), tetrasilane (Si₄H₁₀), and neopentasilane (Si₅H₁₂), and the non-precursor gas includes a halide etchant. Other technical features may be readily apparent to one skilled in the art from the following figures, descriptions, and claims.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced. A more complete understanding of the embodiments of the present disclosure may be derived by referring to the detailed description and claims when considered in connection with the following illustrative figures.

FIG. 1 illustrates a cut-away view of a portion of a semiconductor processing system in accordance with one or more embodiments of the disclosure.

FIG. 2 illustrates a portion of a gas injection system in accordance with one or more embodiments of the disclosure.

FIG. 3 illustrates an additional view of a portion of a gas injection system in accordance with one or more embodiments of the disclosure.

FIG. 4 illustrates a further view of a portion of a gas injection system in accordance with one or more embodiments of the disclosure.

FIG. 5 illustrates an additional exemplary portion of a gas injection system in accordance with one or more embodiments of the disclosure.

FIG. 6 illustrates an exemplary injector nozzle in accordance with one or more embodiments of the disclosure.

FIG. 7 illustrates an exemplary method for forming a silicon-containing layer in a reaction chamber with reduced parasitic deposition in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

The present disclosure pertains to gas injection systems, and associated semiconductor processing systems and methods, designed to minimize, or eliminate, parasitic deposition on the inner surfaces within a reaction chamber. As a non-limiting example, during the formation of silicon-containing layers on a substrate, unwanted reactions can occur on the inner surfaces of the reaction chamber resulting in a parasitic layer of undesirable material on such surfaces. Parasitic deposition can negatively impact the quality of the deposited silicon-containing layer, as well as the operation and lifetime of the semiconductor processing system. Parasitic deposition can be particularly troublesome when employing a transparent reaction chamber, such as those made from quartz materials, for example. In such examples, parasitic deposition can obstruct both incoming radiation (e.g., external radiation from external lamps used for heating) and outgoing radiation (e.g., internal radiation directed towards external monitoring and control systems). In addition, the rate at which parasitic layers are formed on the inner surfaces within the reaction chamber can be detrimentally increased as increased deposition rates and layer thicknesses are sought. For example, enhanced deposition rates for silicon-containing layers may be achieved using higher order silanes as the silicon precursor(s) (e.g., disilane, trisilane, tetrasilane, and the like). These higher-order silanes, characterized by multiple silicon-silicon (Si—Si) bonds, may enhance the deposition rate of a silicon-containing layer but may also increase the risk of undesirable parasitic deposition on the inner surfaces of the reaction chamber, especially at elevated deposition temperatures (e.g., above 500° C.).

To mitigate parasitic deposition within a reaction chamber, various embodiments of the present disclosure provide gas injection systems which include an injector housing comprising a first series of injection ports for introducing a flow of a precursor gas into the reaction chamber and a second series of injection ports for introducing a flow of a non-precursor gas into the reaction chamber. The injector housing is constructed and arranged such that the second series of injection ports are positioned above the first series of injection ports. Employing such an arrangement of separated injection ports allows a flow of non-precursor gas to propagate above the flow of precursor gas, thereby reducing the interaction between the precursor gas and the inner surfaces of the reaction chamber and hence the likelihood of parasitic deposition on the inner surfaces of the reaction chamber. In additional embodiments of the disclosure, the injector housing can also include a third series of injection ports positioned below the first series of injection ports. Employing such an arrangement allows a flow of additional non-precursor gas to propagate below the flow of precursor gas thereby further reducing the interaction between the precursor gas and the inner surfaces of the reaction chamber and hence further mitigating the deposition of a parasitic layer.

As used herein, the term substrate may refer to any underlying material or materials upon which a layer may be deposited. A substrate may include a bulk material, such as silicon (e.g., single-crystal silicon) or other semiconductor material, and may include one or more layers, such as native oxides or other layers, overlying or underlying the bulk material. The substrate may include various topologies, such as recesses, lines, and the like formed within or on at least a portion of a layer and/or bulk material of the substrate. A substrate may comprise one or more materials including, for example, silicon (Si), germanium (Ge), germanium tin (GeSn), silicon germanium (SiGe), silicon germanium tin (SiGeSn), silicon carbide (SIC), or a group III-V semiconductor material, such as, for example, gallium arsenide (GaAs), gallium phosphide (GaP), or gallium nitride (GaN). In some examples, the substrate may comprise one or more dielectric materials including, such as, oxides, nitrides, or oxynitrides. The substrate may comprise a silicon oxide (e.g., SiO₂), a metal oxide (e.g., Al₂O₃), a silicon nitride (e.g., Si₃N₄), or a silicon oxynitride. The substrate may also comprise an engineered substrate where a surface semiconductor layer may be disposed over a bulk support with an intervening buried oxide (BOX) disposed therebetween. The substrate may contain one or more monocrystalline surfaces and/or one or more other surfaces that may comprise a non-monocrystalline surface, such as a polycrystalline surface and/or an amorphous surface. The substrate may include a layer comprising a metal, such as copper, cobalt, and the like.

The terms precursor and/or precursor gases may refer to a gas or combination of gases that participate in a chemical reaction that produces another compound. For example, precursor gases may be used to grow an epitaxial layer comprising silicon. Precursor gases may include a deposition gas, a dopant gas, or a combination of a deposition gas and a dopant gas. Precursors may also be combined with a carrier gas for injecting the precursors gases into a reaction chamber.

The terms non-precursor and/or non-precursor gases may refer to a gas or combination of gasses that do not participate in a chemical reaction for producing another compound. For example, non-precursor gases may be used to etch an epitaxial layer comprising silicon or clean the inner surface of the reaction chamber. Non-precursor gasses may include an etchant gas. Non-precursors may also be combined with a carrier gas for injecting the non-precursor gas into a reaction chamber.

In the following description of the various embodiments, reference is made to the accompanying drawings, which form a part hereof, and in which is shown by way of illustration various embodiments in which aspects of the disclosure may be practiced. It is to be understood that other embodiments may be utilized, and structural and functional modifications may be made without departing from the scope of the present disclosure. Aspects of the disclosure are capable of other embodiments and of being practiced or being carried out in various ways. Also, it is to be understood that the phraseology and terminology used herein are for the purpose of description and should not be regarded as limiting. Rather, the phrases and terms used herein are to be given their broadest interpretation and meaning. The use of “including” and “comprising” and variations thereof is meant to encompass the items listed thereafter and equivalents thereof as well as additional items and equivalents thereof. While various directional arrows are shown in the figures of this disclosure, the directional arrows are not intended to be limiting to the extent that bi-directional communications are excluded. Rather, the directional arrows are to show a general flow of steps and not the unidirectional movement of information. In the entire specification, when an element is referred to as “comprising” or “including” another element, the element should not be understood as excluding other elements so long as there is no special conflicting description, and the element may include at least one other element. Throughout the specification, expressions such as “at least one of a, b, and c” may include “a only,” “b only,” “c only,” “a and b,” “a and c,” “b and c,” and/or “all of a, b, and c.”

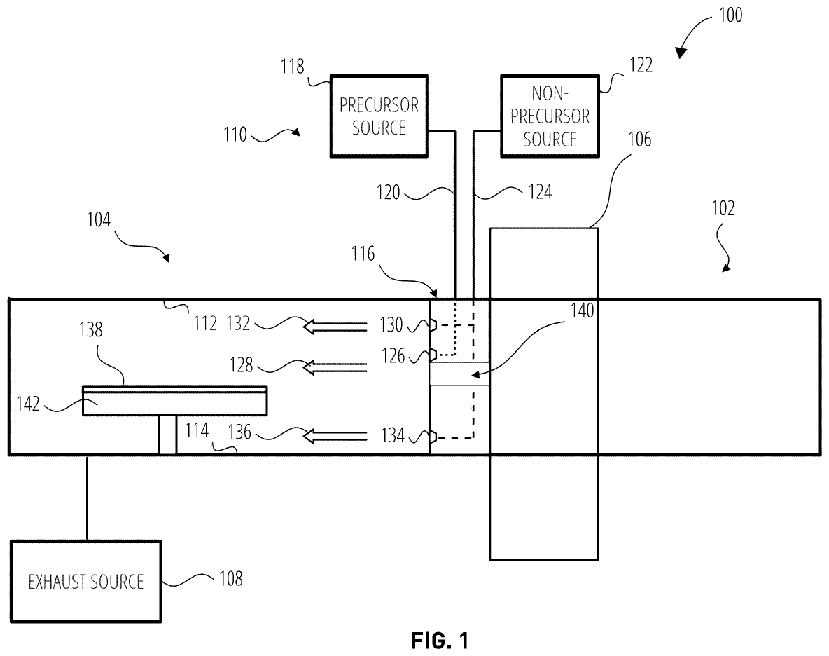

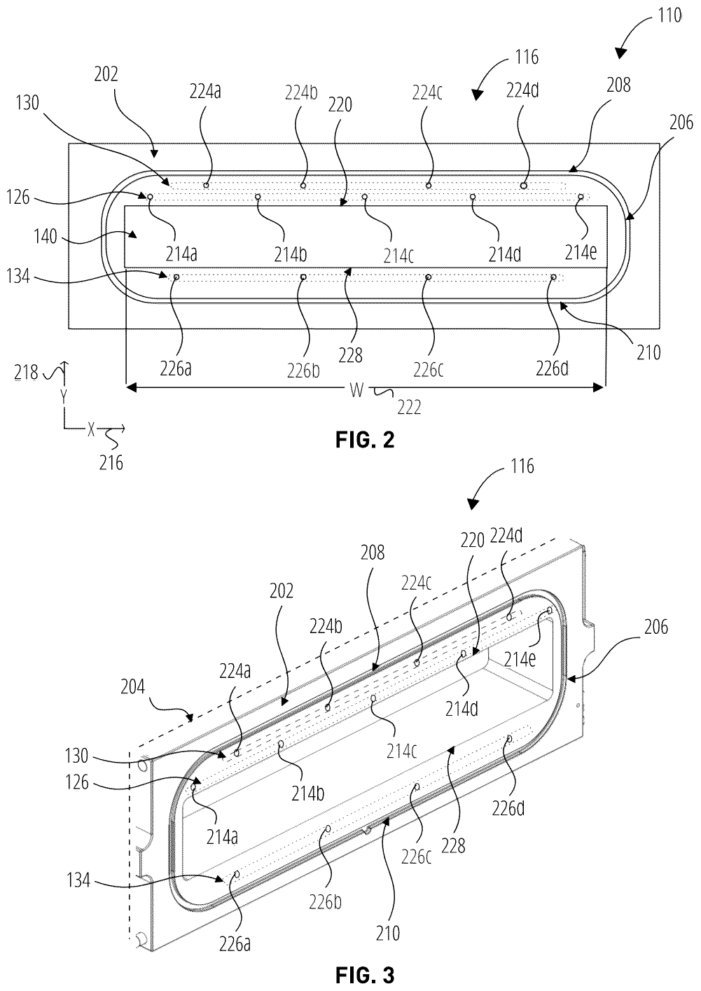

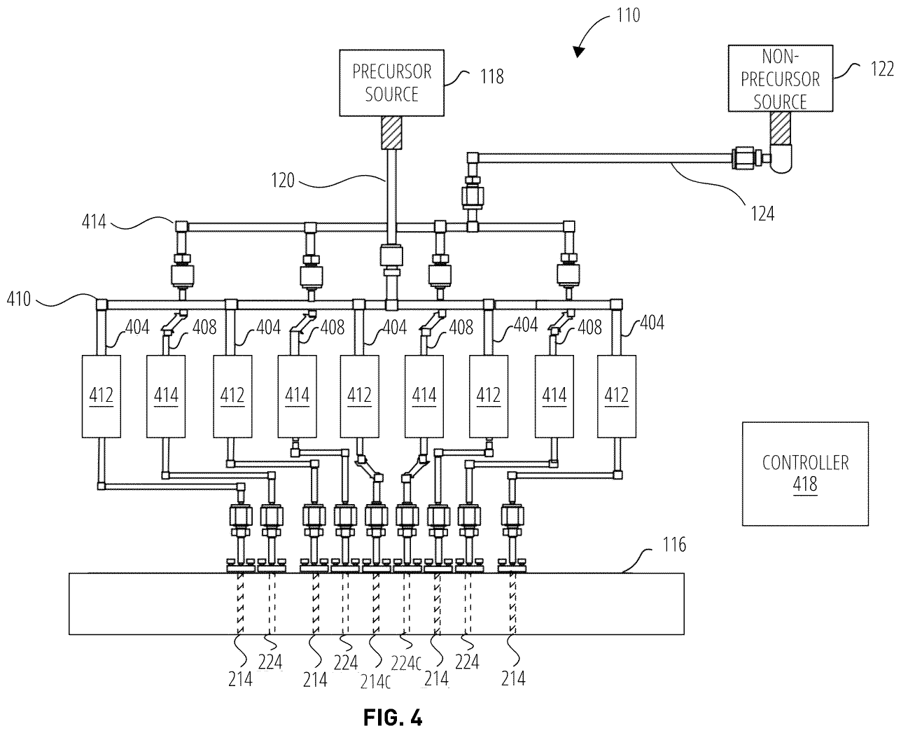

Turning to the figures, FIG. 1 illustrates a cut-away view of a portion of a semiconductor processing system 100 in accordance with one or more embodiments of the disclosure. The semiconductor processing system 100 can be used for a variety of applications, such as chemical vapor deposition (CVD), plasma-enhanced CVD (PECVD), atomic layer deposition (ALD), cleaning processes, etching processes, and the like. Semiconductor processing system 100 may include an optional substrate handling system 102, a reaction chamber 104, an optionally a wall 106 disposed between reaction chamber 104 and the substrate handling system 102, an exhaust source 108, and a gas injection system 110. The gas injection system 110 is illustrated in a simplified form in FIG. 1 and will be described in greater detail below with reference to FIG. 2, FIG. 3, and FIG. 4.

In brief, semiconductor processing system 100 can include any suitable number of reaction chambers 104 and substrate handling systems 102. In some embodiments, the reaction chamber 104 is a cross-flow reaction chamber. In some embodiments, the reaction chamber 104 is a cross-flow reaction chamber configured for performing epitaxial deposition. In some embodiments, the reaction chamber 104 may be fabricated from a transparent material, such as a quartz material, which is substantially transparent to radiant lamp energy provided by radiant lamp heaters (not shown). In some embodiments, the reaction chamber 104 comprises a substantially rectangular, horizontal flow reaction chamber comprising a number of inner surfaces, such as an upper inner surface 112 and a lower inner surface 114, for example.

The semiconductor processing system 100 also includes a gas injection system 110 which is configured to minimize, or eliminate, parasitic deposition on the inner surfaces within the reaction chamber 104. As a non-limiting example, the gas injection systems 110 provided can minimize or eliminate parasitic deposition on the inner surfaces of the reaction chamber, such as, for example, on the upper inner surface 112 and on the lower inner surface 114, and the like.

The gas injection system 110 includes an injector housing 116 which is fluidly connected to a precursor source 118 by a precursor feed line 120. The injector housing 116 is also fluidly connected to a non-precursor source 122 by a non-precursor feed line 124. Although illustrated with two sources 118, 120, each source can include multiple gas sources.

In accordance with examples of the disclosure, the precursor source 118 can include one or more vessels, wherein each vessel contains a precursor. The precursor source 118 can comprise one or more of a silicon precursor, a germanium precursor, a carbon precursor, and a phosphorus precursor. In some embodiments, the silicon precursor comprises a hydrogenated silicon precursor, such as silane (SiH₄), for example. In some embodiments, the silicon precursor comprises a higher order silane including, but not limited to, disilane (Si₂H₆), trisilane (Si₃H₈), tetrasilane (Si₄H₁₀), and neopentasilane (Si₅H₁₂). In some embodiments, the silicon precursor comprises a silicon halide precursor. In one aspect the silicon halide precursor is a silicon chloride precursor such as, for example, one or more of monochlorosilane (MCS), dichlorosilane (DCS), trichlorosilane (TCS), hexachlorodisilane (HCDS), octachlorotrisilane (OCTS), and silicon tetrachloride (STC). In another aspect the silicon halide precursor is a silicon iodide precursor such as, for example, an iodosilane (e.g., monoiodosilane, diiodosilane, triiodosilane, and tetraiodosilane). In some embodiments, the precursor source 118 also includes a dopant source comprising one or more of As, P, C, Ge, and B. In some embodiments, the precursor source 118 also includes carrier gas source comprising one or more of hydrogen, nitrogen, argon, helium, and the like.

In accordance with examples of the disclosure, the non-precursor source 122 can include one or more vessels, wherein each vessel contains a non-precursor source, such as an etchant source. As stated previously the non-precursor source 122 does not include precursor gas sources, such as, sources of silicon precursor(s), germanium precursor(s), phosphorus precursor(s), and the like. In some embodiments, the etchant source comprises a gaseous etchant, such as a gaseous halide etchant. In some embodiments, the gaseous etchant comprises a gaseous chlorine-containing etchant. In such embodiments, the gaseous chlorine-containing etchant can comprise at least one of chlorine (Cl₂), or hydrochloric acid (HCl). In some embodiments, the carrier gas source comprises one or more of hydrogen, nitrogen, argon, helium, and the like.

In accordance with examples of the disclosure, the injector housing 116 includes a first series of injection ports 126 (shown here in cross-section and described in greater detail below) constructed and arranged for introducing a precursor gas (as illustrated by precursor gas flow 128) into the reaction chamber 104 and a second series of injection ports 130 (shown here in cross-section and described in greater detail below) constructed and arranged for introducing a non-precursor gas (as illustrated by non-precursor gas flow 132) into the reaction chamber 104. As illustrated in FIG. 1, the non-precursor gas flow 132 is situated between the precursor gas flow 128 and the upper inner surface 112 of the reaction chamber 104, thereby reducing, or preventing, interactions between the precursor gas flow 128 and the upper inner surface 112 of the reaction chamber 104. In additional embodiments of the disclosure, the injector housing 116 also includes a third series of injection ports 134 (shown here in cross-section and described in greater detail below) constructed and arranged for introducing an additional non-precursor gas (as illustrated by additional non-precursor gas flow 136) into the reaction chamber 104. In such embodiments, the additional non-precursor gas flow 136 is situated between precursor gas flow 128 and the lower inner surface 114 of the reaction chamber 104, thereby reducing, or preventing, interactions between precursor gas flow 128 and the lower inner surface 114 of the reaction chamber 104. In FIG. 1, precursor gas flow 128, non-precursor gas flow 132, and additional non-precursor gas flow 136 are illustrated as being introduced as horizontal flows, i.e., substantially parallel to the upper surface of the substrate 138. However, in some embodiments, the first series of injection ports 126, the second series of injection ports 130, and the third series of injection ports 134, can be constructed and arranged to introduce the process gas flows (128, 132, and 136) at different flow angles, e.g., above or below the horizontal as illustrated in FIG. 1. In a particular example, the first series of injection ports 126 can be constructed and arranged to introduce the precursor gas flow 128 at an angle below the horizon, i.e., the precursor gas flow is directed downward into the reaction chamber 104 at direction towards the lower inner surface 114 of the reaction chamber 104.

During operation of semiconductor processing system 100, substrates (e.g., substrate 138 of FIG. 1) are introduced into the reaction chamber by being transferred from the substrate handling system 102 through the substrate channel 140. The substrate 138 is then seated on a support assembly 142. The support assembly 142 disposed within the reaction chamber 104 is configured for supporting the substrate 138 during deposition processes within the reaction chamber 104. Once substrates are transferred to reaction chamber 104, precursor gas from the precursor source 118 (along with carrier, dopant gases as needed) and non-precursor gas from the non-precursor source 122 (along with carrier gases as needed) are introduced into reaction chamber 104 via gas injection system 110. As set forth in more detail below, gas injection system 110 is constructed and arranged to reduce, or prevent, parasitic deposition on the inner surfaces of the reaction chamber 104, such as upper inner surface 112 and lower inner surface 114. A more detailed description of the gas injection system 110 will be provided with reference to FIG. 2, FIG. 3 and FIG. 4.

FIG. 2, FIG. 3, and FIG. 4 illustrate a portion of a gas injection system 110 of the present disclosure including an injector housing 116. FIG. 2 illustrates a front view of the injector housing 116, and FIG. 3 illustrates an isometric cut-away view of a portion of the injector housing 116.

In more detail, the injector housing 116 (as illustrated in FIG. 2 and FIG. 3) can be formed of any suitable material, such as stainless steel, Hastelloy, and the like. The injector housing 116 includes a front face 202 configured for coupling to a reaction chamber (such as reaction chamber 104 of FIG. 1), a rear face 204, and a substrate channel 140 extending through the injector housing 116 from the front face 202 to the rear face 204. The substrate channel 140 is sized to allow the insertion and extraction of substrates through the injector housing 116 for loading/unloading operations. The injector housing 116 also includes a groove 206 disposed in the front face 202. The groove 206 includes an upper surface of the groove 208 and a lower surface of the groove 210. The groove 206 surrounds the substrate channel 140 and is configured to receive a sealing element (not shown) such as an O-ring, for example.

In accordance with examples of the disclosure, injector housing 116 includes a first series of injection ports 126 disposed in the front face 202 of the injector housing 116. The first series of injection ports 126 (shown collectively by the dashed line) are constructed and arranged for introducing a precursor gas from a precursor source (e.g., precursor source 118 of FIG. 1) into a reaction chamber. In some embodiments, the first series of injection ports 126 include a first plurality of injection ports 214a, 214b, 214c, 214c, 214d, and 214c. Although the first series of injection ports 126 is illustrated as comprising five individual injection ports it is anticipate that a greater number or lesser number of individual injection ports can collectively comprises the first series of injection ports 126. In accordance with examples of the disclosure, the first series of injection ports 126 are positioned above the substrate channel 140.

In some embodiments, the first series of injection ports 126 (i.e., injection ports 214a, 214b, 214c, 214c, 214d, and 214c) are commonly aligned with each along a common position on the y-axis 218. In such aspects, the first series of injection ports are positioned at a common distance from an upper surface of the substrate channel 220. In some embodiments, the first series of injection ports 126 are positioned at a distance between 1 mm and 50 mm, or between 2 mm and 25 mm, or between 5 mm and 25 mm, from the upper surface of the substrate channel 220. In alternative embodiments, the first series of injection ports 126 (i.e., injection ports 214a, 214b, 214c, 214c, 214d, and 214c) are not commonly aligned to each other and each injection port may be positioned at a different position along the y-axis, although still remaining above the substrate channels 140 and below the second series of injection ports 130.

In some embodiments, each injection port of the first series of injection ports 126 (e.g., 214a, 214b, 214c, 214c, 214d, and 214c) is spaced equidistant from the adjacent injection port (i.e., the first plurality of injection ports is each equally spaced along the x-axis 216). In some embodiments, each injection port of the first series of injection ports 126 is spaced a distance between 1 and 50 mm, or between 5 mm and 40 mm, or between 10 mm and 25 mm, from the adjacent injection port. In another aspect, each injection port of the first series of injection ports 126 (e.g., 214a, 214b, 214c, 214c, 214d, and 214c) is not spaced equidistant from the adjacent injection port (i.e., the first plurality of injection ports are not equally spaced along the x-axis 216).

In some embodiments, the first series of injection ports 126 are orientated parallel to the substrate channel 140, e.g., the first plurality of injection ports (214a, 214b, 214c, 214c, 214d, and 214c) are orientated in parallel with the upper surface of the substrate channel 220.

In some embodiments, the first series of injection ports 126 are confined within the width of the substrate channel 140, as illustrated by width (W) 222 in FIG. 1. In other embodiments, the first series of injection ports 126 can extended beyond the width (W) 222 of the substrate channel 140.

In some embodiments, the first series of injection ports 126 are positioned within the perimeter defined by the groove 206.

In accordance with examples of the disclosure, injector housing 116 includes a second series of injection ports 130 disposed in the front face 202 of the injector housing 116. The second series of injection ports 130 are constructed and arranged for introducing a non-precursor gas from a non-precursor source (e.g., non-precursor source 122 of FIG. 1) into a reaction chamber. In some embodiments, the second series of injection ports 130 includes a second plurality of injection ports 224a, 224b, 224c, and 224d. Although the second series of injection ports 130 is illustrated as comprising four individual injection ports (e.g., FIG. 2) it is anticipated that a greater number or lesser number of individual injection ports can collectively comprises the second series of injection ports 130. In such embodiments, the second series of injection ports 130 are positioned above the substrate channel 140. In such examples, the second series of injection ports 130 are positioned above the first series of injection ports 126.

In some embodiments, the second series of injection ports 130 (i.e., injection ports 224a, 224b, 224c, and 224d) are commonly aligned with each along a common position on the y-axis 218. In such aspects, the second series of injection ports 130 are positioned at a common distance from an upper surface of the substrate channel 220. In some embodiments, the second series of injection ports 130 are positioned at a distance between 5 mm and 50 mm, or between 10 mm and 25 mm, or between 15 mm and 25 mm, from the upper surface of the substrate channel 220. In some embodiments, the second series of injection ports 130 are positioned at a distance between 1 mm and 50 mm, or between 2 mm and 25 mm, or between 5 mm and 25 mm, from upper surface of the groove 208.

In accordance with examples of the disclosure, the second series of injection ports 130 are positioned above the first series of injection ports 126. In some embodiments, the second series of injection ports 130 are positioned at a common distance from the first series of injection ports 126 (i.e., the distance in the y-axis from 126 to 130) In some embodiments, the second series of injection ports 130 are positioned at a distance of between 1 mm and 50 mm, or between 2 mm and 25 mm, or between 5 mm and 25 mm from the first series of injection ports 126.

In alternative embodiments, the second series of injection ports 130 (e.g., 224a, 224b, 224c, and 224d) are not commonly aligned to each other and each injection port may be positioned at a different position along the y-axis, although remaining above both the substrate channels 140 and the first series of injection ports 126.

In some embodiments, each injection port of the second series of injection ports 130 (e.g., 224a, 224b, 224c, and 224d) is spaced equidistant from the adjacent injection port (i.e., the second series of injection ports 130 are each equally spaced along the x-axis 216). In some embodiments, each injection port of the second series of injection ports 130 is spaced a distance between 1 and 50 mm, or between 5 mm and 40 mm, or between 10 mm and 25 mm, from the adjacent injection port. In another aspect, each injection port of the second series of injection ports 130 (e.g., 224a, 224b, 224c, and 224d) is not spaced equidistant from the adjacent injection port (i.e., the second plurality of injection ports are not equally spaced along the x-axis 216). In some embodiments, one or more the injection ports of the second series of injection ports 130 can be positioned proximate to the inner perimeter of the groove 206 to enable non-precursor gas flow proximate to the groove 206.

In some embodiments, each injection port of the second series of injection ports 130 (e.g., 224a, 224b, 224c, and 224d) is positioned at the mid-point (i.e., the center point) in the x-axis 216 between adjacent injection ports of the first series of injection ports 126. For example, and with reference to FIG. 2, the second injection port 224a is position in the x-axis 216 at the mid-point between the first injection port 214a and the first injection port 214b. In alternative embodiments, each injection port of the second series of injection ports 130 can be position at differing position along the x-axis in relation to the underlying first series of injection ports 126.

In some embodiments, the second series of injection ports 130 are orientated parallel to the substrate channel 140, e.g., the second series of injection ports 130 (e.g., 224a, 224b, 224c, and 224d) are orientated in parallel with the upper surface of the substrate channel 220. In some embodiments, the second series of injection ports 130 are orientated parallel to the first series of injection ports 126. In some embodiments, the second series of injection ports 130 are orientated parallel to both the first series of injection ports 126 and the upper surface of the substrate channel 220.

In some embodiments, the second series of injection ports 130 are confined within the width of the substrate channel 140, as illustrated by width (W) 222 in FIG. 1. In other embodiments, the second series of injection ports 130 can extended beyond the width (W) 222 of the substrate channel 140.

In some embodiments, the second series of injection ports 130 are positioned within the perimeter defined by the groove 206.

In accordance with examples of the disclosure, injector housing 116 can also optionally include a third series of injection ports 134 in the front face 202 of the injector housing 116. The third series of injection ports 134 are constructed and arranged for introducing an additional non-precursor gas from the non-precursor source (e.g., non-precursor source 122 of FIG. 1) into a reaction chamber. In some embodiments, the third series of injection ports 134 includes a third injection port 226a, 226b, 226c, 226d. Although the third series of injection ports 134 is illustrated as comprising four individual injection ports it is anticipate that a greater number or lesser number of individual injection ports can collectively comprises the third series of injection ports 134. In such embodiments, the third series of injection ports 134 are positioned below the substrate channel 140. In such examples, the third series of injection ports 134 are positioned below the first series of injection ports 126.

In some embodiments, the third series of injection ports 134 (i.e., injection ports 226a, 226b, 226c, 226d) are commonly aligned with each along a common position on the y-axis 218. In such aspects, the third series of injection ports 134 are positioned at a common distance from a lower surface of the substrate channel 228. In some embodiments, the third series of injection ports 134 are positioned at a distance between 1 mm and 50 mm, or between 2 mm and 25 mm, or between 5 mm and 25 mm, from the lower surface of the substrate channel 228.

In alternative embodiments, the third series of injection ports 134 (e.g., 226a, 226b, 226c, 226d) are not commonly aligned to each other and each injection port may be positioned at a different position along the y-axis, although remaining above below the substrate channels 140 and the first series of injection ports 126.

In some embodiments, each injection port of the third series of injection ports 134 (e.g., 226a, 226b, 226b, 226d) is spaced equidistant from the adjacent injection port (i.e., the third series of injection ports 134 are each equally spaced along the x-axis 216). In some embodiments, each injection port of the third series of injection ports 134 is spaced a distance between 1 and 50 mm, or between 5 mm and 40 mm, or between 10 mm and 25 mm, from the adjacent injection port. In some embodiments, each of the injections port of the third series of injection ports 134 is positioned directly below a corresponding injection port of the second series of injection ports 130. In another aspect, each injection port of the third series of injection ports 134 (e.g., 226a, 226b, 226c, 228d) is not spaced equidistant from the adjacent injection port (i.e., the second plurality of injection ports are not equally spaced along the x-axis 216). In some embodiments, one or more the injection ports of the third series of injection ports 134 can be position proximate to the inner perimeter of the groove 206 to enable additional non-precursor gas flow proximate to the groove 206.

In some embodiments, each injection port of the third series of injection ports 134 (e.g., 226a, 226b, 226c, 226d) is positioned at the mid-point (i.e., the center point) in the x-axis 216 between adjacent injection ports of the first series of injection ports 126. For example, and with reference to FIG. 2, the second injection port 224a is position in the x-axis 216 at the mid-point between the first injection port 214a and the first injection port 214b. In alternative embodiments, each injection port of the second series of injection ports 130 can be position at differing position along the x-axis in relation to the underlying first series of injection ports 126.

In some embodiments, the third series of injection ports 134 are orientated parallel to the substrate channel 140, e.g., the third series of injection ports 134 (e.g., 226a, 226b, 226c, 226d) are orientated in parallel with the lower surface of the substrate channel 228. In some embodiments, the third series of injection ports 134 are orientated parallel to the first series of injection ports 126. In some embodiments, the third series of injection ports 134 are orientated parallel to both the first series of injection ports 126 and the lower surface of the substrate channel 228. In some embodiments, the third series of injection ports 134 are orientated parallel to the first series of injection ports 126, the second series of injection ports 130, and the lower surface of the substrate channel 228.

In some embodiments, the third series of injection ports 134 are confined within the width of the substrate channel 140, as illustrated by width (W) 222 in FIG. 1. In other embodiments, the third series of injection ports 134 can extended beyond the width (W) 222 of the substrate channel 140.

In some embodiments, the third series of injection ports 134 are positioned within the perimeter defined by the groove 206.

FIG. 4 schematically illustrates a further portion of the gas injection system 110 in accordance with exemplary embodiments of the disclosure. As illustrated in FIG. 4 the gas injection system 110 includes an injector housing 116, as described in detail above in connection with FIG. 2 and FIG. 3. When referring to gas lines and fluid components of gas injection system 110 of FIG. 4, the term coupled refers to fluidly coupled, and, unless stated otherwise, the lines or components need not be directly fluidly coupled, but rather the gas injection system 110 can include other intervening elements, such as connectors, valves, meters, or the like.

In accordance with examples of the disclosure, the gas injection system 110 (as illustrated in FIG. 4) supplies precursor gas from the precursor source 118, which is fed via precursor feed line 120 to a first manifold 410. The first manifold 410 includes one or more (e.g., a plurality) of first gas lines 404 which supply the precursor gas to the injector housing 116 employing a plurality of first flow controllers 412 to individual control the flow of the precursor gas to each of the first series of injection ports 126 (e.g., first injection ports 214a, 214b, 214c, 214d, 214c).

In accordance with further examples of the disclosure, the gas injection system 110 (as illustrated in FIG. 4) supplies the non-precursor gas from the non-precursor source 122, which is fed via non-precursor feed line 124 to a second manifold 416. The second manifold 416 includes one or more (e.g., a plurality) of second gas lines 408 which supply the non-precursor gas to the injector housing 116 employing a plurality of second flow controllers 414 to individual control the flow of the non-precursor gas of the second series of injection ports 130 (e.g., second injection ports 224a, 224b, 224c, 224d).

Although not illustrated in FIG. 4, in some embodiments, the gas injection system 110 supplies additional non-precursor gas from the non-precursor source 122, which is fed via the non-precursor feed line 124 to the third series of injection ports, in a similar manner as described above in relation to the supply of the non-precursor gas to the second series of injection ports. In some embodiments, the third first series of injection ports is fed from the second manifold 416 via the second gas lines 408 and the plurality of second flow controllers 414. In other embodiments, the gas injection system 110 of FIG. 4 can employ an additional third manifold and third gas lines (not illustrated) to supply the addition non-precursor gas to the third series of injection ports.

In accordance with examples of the disclosure, each of the first series of injection ports 126 (e.g., injection ports 214a, 214b, 214c, 214d, 214c) corresponds one-to-one with each of the plurality of first flow controllers 412.

In accordance with additional examples of the disclosure, each of the second series of injection ports 130 (e.g., injection ports 224a, 224b, 224c, 224d) corresponds one-to-one with each of the plurality of second flow controllers 414.

In the illustrated example, the injector housing 116 includes five first gas lines 404 feeding the first series of injection ports (e.g., 214a, 214b, 214c, 214d, 214c) and four second gas lines 408 feeding the second series of injection ports (e.g., 224a, 224b, 224c, 224d). However, gas injection system 110 can have the same or similar number of corresponding first gas lines 404 and/or second gas lines 408 that are coupled to the respective injection ports. Use of multiple channels and injections ports for each source gas (e.g., precursor source 118 and non-precursor source 122) allows fine control and tuning from each gas source of flow rates to multiple independent locations within a reaction chamber, such as reaction chamber 104 of FIG. 1. This, in turn, allows independent control of film properties across a surface of a substrate.

In accordance with examples of the disclosure, gas injection system 110 (of FIG. 4) includes a plurality of first flow controllers 412 which can additionally include a plurality of flow sensors. In the illustrated example, each of the first series of injection ports and the second series of injection ports are coupled to a single flow controller 412, 414. However, in some cases, it may be desirable to have some gas outlets that are not coupled to a flow controller and/or to have some gas outlets that are coupled to more than one flow controller.

The plurality of first flow controllers 412 and the plurality of second flow controllers 414 can be used to monitor and control flow rates of gas mixtures and to provide real-time and/or historical flow rate information to a user for each first gas lines 404 and each second gas lines 408—e.g., using a graphical user interface. Additionally, or alternatively, the plurality of first flow controllers 412 and the plurality of second flow controllers 414 can be coupled to a controller (e.g., controller 418) to provide controlled flow ratio of the gases to the injector housing 116. By placing at least one flow controller in each gas first gas lines 404 and second gas lines 408, the flow ratio (e.g., relative flow rate) of gas through each gas line can be measured and controlled, regardless of the gas composition. Exemplary flow controllers (412, 414) can be or include various flow sensors, e.g., thermal mass flow sensors, pressure drop based flow sensors, or the like.

The plurality of first flow controllers 412 and the plurality of second flow controllers 414 can also include any suitable device to meter flow of a gas. In accordance with various embodiments of the disclosure, flow controllers (414, 416) can each comprise proportional valves, such as solenoid valves, pneumatic valves, or piezoelectric valves. Flow controllers with a relatively high (e.g., 0.021-0.14) flow coefficient (Cv) may be selected to reduce chocking downstream. Flow controllers (412, 414) may desirably operate under closed-loop control, but may also be capable (e.g., additionally) of operating under open-loop control.

The plurality of first flow controllers 412 and the plurality of second flow controllers 414 can initially form part of, for example, a mass flow controller (e.g., an off-the-shelf mass flow controller), wherein controller 418 replaces the control function of the valve. For example, flow controllers (412, 414) can form or be part of a mass flow controller that is set to operate in open-loop mode and wherein controller 418 provides closed-loop control of plurality of flow controllers (412, 414).

Controller 418 can be configured to perform various functions and/or steps as described herein. Controller 418 can include one or more microprocessors, memory elements, and/or switching to perform the various functions. Although illustrated as a single unit, controller 418 can alternatively comprise multiple devices. By way of examples, controller 418 can be used to control flow of gas from precursor source 118 and/or non-precursor source 122 in the first gas lines 404 and the second gas lines 408, which can fluidly connect the injection ports (e.g., first, second, and third series of injection ports) of the injector housings 116, and optionally to reaction chamber 104 (of FIG. 1). Controller 418 can be configured to provide open-loop and/or closed-loop flow control using, for example, the same hardware. Controller 418 can be configured to provide desired ratios of a total flow of a respective gas (e.g., from precursor source 118 and/or non-precursor source 122) in each of the gas lines feeding the injector housing. In accordance with various examples of the disclosure, controller 418 includes proportional-integral-derivative (PID) controllers, which allow independent, closed-loop control of the flow controllers (412, 414). With PID closed-loop control, gas injection system 110 (FIG. 4) can dynamically adjust flows in one or more (e.g., all) gas lines (e.g., 404, 408) to set points and/or provide stable, especially initial, flow rates of gases to reaction chamber when switching between gas sources and/or when the operating pressure is relatively high (e.g., near atmospheric pressure). The closed-loop control allows for automatic and stable control of flow rates through each of the gas line (404, 408) over a wide variety of pressure ranges, such as those set forth herein. The closed-loop control further allows for control without tool matching, which is often desired for traditional systems. By way of example, using PID control, an provide initial set points for each of the flow controllers (412, 414). Flow ratio feedback from an output of each flow controller can then be used in connection with a PID controller of controller 418 to control the desired set point (i.e., flow ratio) of each of the flow controllers (412, 414).

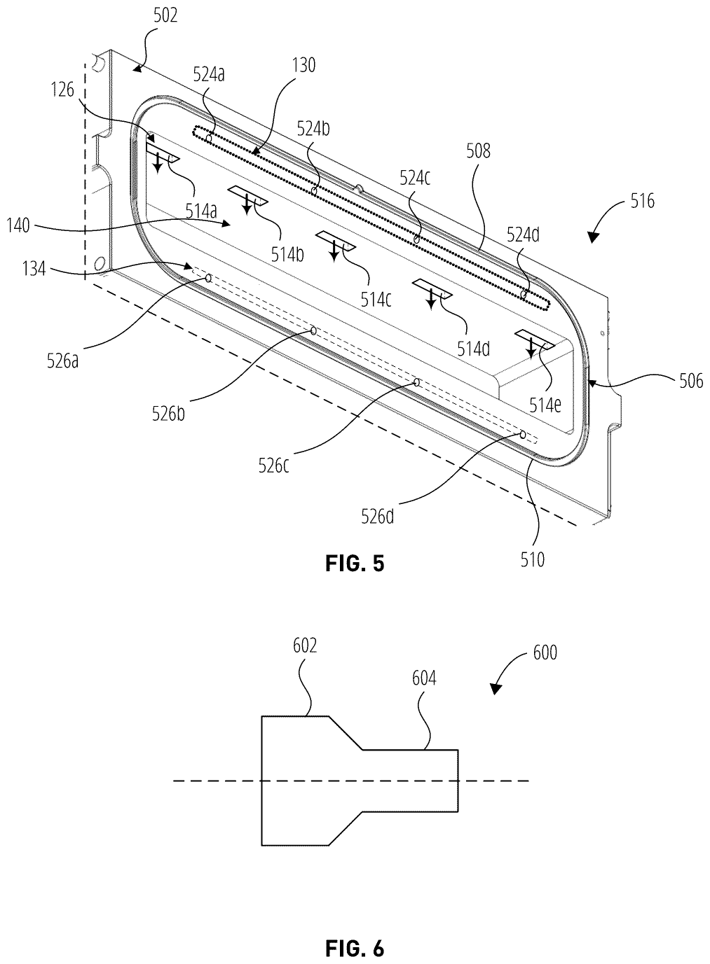

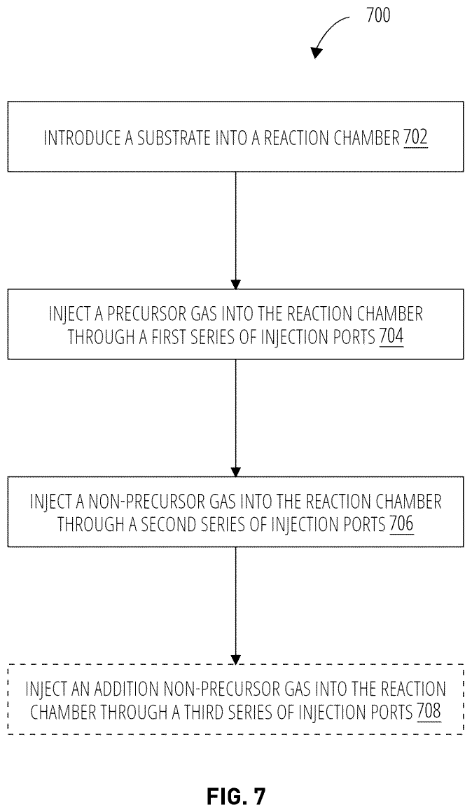

FIG. 5 illustrates an additional exemplary injector housing 516 in accordance with various embodiments of the disclosure. Injector housing 516 comprises a first series of injection ports 126 disposed in the front face 502 of the injector housing. The first series of injection ports of injector housing 516 can include injection ports 514a, 514b, 514c, 514d, 514c, for example. As illustrated in FIG. 5, the exemplary first series of injection ports (514a-514c) can be disposed in the front face 502 of the housing within the substrate channel 140, where the exemplary process gas flow is directed towards the substrate channel 140 and therefrom into the reaction chamber.

In various embodiment, injector housing 516 comprises a second series of injection ports 130 (e.g., exemplary injections ports 524a-524d) disposed in the front face 502 of the injector housing and positioned above the first series of injections ports (e.g., exemplary injection ports 514a-514c). Injector housing 516 can comprise groove 506 disposed in the front face 502, the groove surrounding the substrate channel 140. In some embodiments, the second series of injection ports (e.g., 524a-524d) are positioned between the first series of injection ports (e.g., 514a-514c) and an upper surface 508 of the groove 506.

In certain examples, injector housing 516 may further comprise a third series of injection ports 134 (as illustrated in FIG. 5 by exemplary injection ports 526a-526d) positioned between the substrate channel and a lower surface 510 of the groove 506. In such examples, the third series of injection ports (e.g., injection ports 526a-526d) are in fluid communication with a second manifold comprising the plurality of second flow controllers configured to control a flow of the non-precursor gas from the non-precursor source to the third series of injection ports, as previously described above.

In certain embodiments, a high velocity gas curtain can be utilized in the reaction chambers to protect surfaces from corrosive or depositing materials generated during reactions. This protective gas curtain can be formed by introducing a high-velocity gas stream, which acts as a barrier between the reactive environment and the surfaces needing protection, such as the upper inner surface of the chamber. In various embodiments, a high-velocity gas stream may be employed to reduce contact between precursor gases and interior chamber surfaces, and/or in processes like chemical vapor deposition, a high-velocity curtain can prevent particles from settling on surfaces, maintaining chamber cleanliness and function.

In certain embodiments, the injection ports of the second series of injection ports (and if present the third series of injection ports) can comprise injector nozzles constructed and arranged for generating high velocity gas streams into the reaction chamber. In such embodiments, the cross-section of such injector nozzles can vary in shape to optimize the gas flow dynamics.

As a non-limiting example, a converging nozzle may be utilized (as exemplified in FIG. 6). For examples, FIG. 6 illustrates a cross-sectional view of a converging nozzle 600 that has a decreasing diameter towards the exit. In more detail, converging nozzle 600 can comprise a gas input portion 602 and a gas exit portion 604, wherein the gas input portion 602 has a higher diameter than the gas exit portion 604. Such a converging nozzle can accelerate the gas to high speeds as it exits the nozzle (600) and is injected into the reaction. Such an injector geometry can be effective for creating a high-pressure, high-velocity gas stream for gas curtain applications. Alternative cross-sections can be employed for the injector nozzles (e.g., of 524a-524d and/or 526a-526d), including but not limited to converging-diverging (De Laval) nozzles (e.g., having a converging section followed by a diverging section), straight-bore nozzles (e.g., having a constant diameter throughout its length), slit nozzles (e.g., characterized by a narrow, elongated opening, to produces a planar jet of gas), or radial flow nozzles (e.g., nozzles configured distribute gas in a radial pattern).

The various embodiments of the disclosure also provide methods for forming a silicon-containing layer on a substrate within a reaction chamber, the reaction chamber including an upper inner surface and a lower inner surface. The methods of the disclosure can additional be employed for forming germanium (Ge) layers on a substrate within a reaction chamber.

An exemplary method of the disclosure is illustrated with reference to process 700. In accordance with examples of the disclosure, the process 700 comprises introducing a substrate into the reaction chamber through a substrate channel extending through an injector housing of a gas injection system and seating the substrate on a support assembly (step 702).

In accordance with examples of the disclosure, process 700 includes injecting a precursor gas into the reaction chamber through a first series of injection ports disposed in a front face of the injector housing (step 704).

In accordance with examples of the disclosure, process 700 includes injecting a non-precursor gas into the reaction chamber through a second series of injection ports disposed in the front face of the injector housing above the first series of injection ports (step 706).

As describe herein and illustrated in FIG. 1, the non-precursor gas injected from the second series of injection ports (e.g., non-precursor gas flows 132 of FIG. 1) provides a gas curtain above the precursor gas (e.g., precursor gas flow 128 of FIG. 1). In accordance with examples of the disclosure, the gas curtain is positioned between the precursor gas flow 128 and the upper inner surface 112 of the reaction chamber 104, thereby reducing parasitic deposition on the upper inner surface 112. Therefore, the methods provide a gas curtain between the precursor gas and the upper inner surfaces of the reaction chamber thereby reducing parasitic deposition on the upper inner surface.

In accordance with additional examples of the disclosure, process 700 can optionally include injecting an addition non-precursor gas into the reaction chamber through a third series of injection ports disposed in the front face of the injector housing below the substrate channel (optional step 708).

As describe herein and illustrated in FIG. 1, the additional non-precursor gas injected from the third series of injection ports (e.g., additional non-precursor gas flow 136 of FIG. 1) provides an additional gas curtain below the precursor gas (e.g., precursor gas flow 128 of FIG. 1). In accordance with examples of the disclosure, the additional gas curtain is positioned between the precursor gas flow 128 and the lower inner surfaces 114 of the reaction chamber 104, thereby reducing parasitic deposition on the lower inner surface 114. Therefore, the methods provide an additional gas curtain between the precursor gas and the lower inner surfaces of the reaction chamber thereby reducing parasitic deposition on the lower inner surfaces.

In some embodiments, the precursor gas comprises at least one of disilane (Si₂H₆), trisilane (Si₃H₈), tetrasilane (Si₄H₁₀), and neopentasilane (Si₅H₁₂), and the non-precursor gas comprises a halide etchant. In other embodiments, additional and/or alternative precursor gases and non-precursor gases may be utilized as described in detail previously.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A gas injection system for supplying a gas into a reaction chamber, comprising:
an injector housing including a front face and a rear face;
a substrate channel extending through the injector housing from the front face to the rear face;
a first series of injection ports disposed in the front face of the injector housing, wherein the first series of injection ports are positioned above the substrate channel and are in fluid communication with a first manifold, the first manifold comprising a plurality of first flow controllers configured to control a flow of a precursor gas from a precursor source to the first series of injection ports; and
a second series of injection ports disposed in the front face of the injector housing, wherein the second series of injection ports are positioned above the first series of injection ports and are in fluid communication with a second manifold, the second manifold comprising a plurality of second flow controllers configured to control a flow of a non-precursor gas from a non-precursor source to the second series of injection ports.

2. The gas injection system of claim 1, wherein the first series of injection ports comprises a first plurality of injection ports which are commonly aligned to each other.

3. The gas injection system of claim 2, wherein each of the second series of injection ports comprises a second plurality of injection ports commonly aligned to each other.

4. The gas injection system of claim 3, wherein the first series of injection ports are orientated parallel to the second series of injection ports.

5. The gas injection system of claim 4, further comprising a groove disposed in the front face of the injector housing, the groove surrounding the substrate channel, wherein the second series of injection ports are positioned between the first series of injection ports and an upper surface of the groove.

6. The gas injection system of claim 5, further comprising a third series of injection ports positioned between the substrate channel and a lower surface of the groove, wherein the third series of injection ports are in fluid communication with the second manifold comprising the plurality of second flow controllers configured to control a flow of the non-precursor gas from the non-precursor source to the third series of injection ports.

7. The gas injection system of claim 1, wherein each injection port of the first series of injection ports corresponds one-to-one with each of the plurality of first flow controllers, and each of the second series of injection ports correspond one-to one with each of the plurality of second flow controllers.

8. The gas injection system of claim 1, wherein the precursor source comprises a silicon precursor including at least one of disilane (Si₂H₆), trisilane (Si₃H₈), tetrasilane (Si₄H₁₀), and neopentasilane (Si₅H₁₂).

9. The gas injection system of claim 1, wherein the non-precursor source comprises at least an etchant source comprising a halide etchant.

10. A semiconductor processing system, comprising:
a reaction chamber comprising an upper inner surface and a lower inner surface;
a support assembly for supporting a substrate within the reaction chamber; and
a gas injection system for supplying gas into the reaction chamber, the gas injection system comprising:
an injector housing including a front face and a rear face;
a substrate channel extending through the injector housing from the front face to the rear face;
a first series of injection ports disposed in the front face of the injector housing, wherein the first series of injection ports are positioned above the substrate channel and are in fluid communication with a first manifold comprising a plurality of first flow controllers configured to control a flow of a precursor gas from a precursor source to the first series of injection ports; and
a second series of injection ports disposed in the front face of the injector housing,
wherein the second series of injection ports are positioned between the first series of injection ports and the upper inner surface of the reaction chamber and are in fluid communication with a second manifold comprising a plurality of second flow controllers configured to control a flow of a non-precursor gas from a non-precursor source to the second series of injection ports; and
an exhaust source positioned downstream of the gas injection system.

11. The semiconductor processing system of claim 10, wherein the first series of injection ports comprises a first plurality of injection ports which are commonly aligned to each other.

12. The semiconductor processing system of claim 11, wherein the second series of injection ports comprises a second plurality of injection ports which are commonly aligned to each other.

13. The semiconductor processing system of claim 12, wherein the first series of injection ports is parallel to the second series of injection ports.

14. The semiconductor processing system of claim 13, further comprising a groove disposed in the front face of the injector housing, the groove surrounding the substrate channel, wherein the second series of injection ports are positioned between the first series of injection ports and an upper surface of the groove.

15. The semiconductor processing system of claim 14, further comprising a third series of injection ports disposed in the front face of the injector housing and positioned between the substrate channel and a lower surface of the groove, wherein the third series of injection ports are in fluid communication with the second manifold comprising the plurality of second flow controllers configured to control a non-precursor gas flow from the non-precursor source to the third series of injection ports.

16. The semiconductor processing system of claim 10, wherein each injection port of the first series of injection ports correspond one-to-one with each of the plurality of first flow controllers, and each of the second series of injection ports correspond one-to one with each of the plurality of second flow controllers.

17. The semiconductor processing system of claim 10, wherein the precursor source comprises a silicon precursor including at least one of disilane (Si₂H₆), trisilane (Si₃H₈), tetrasilane (Si₄H₁₀), and neopentasilane (Si₅H₁₂).

18. A method for forming a silicon-containing layer within a reaction chamber including an upper inner surface and a lower inner surface, the method comprising:
introducing a substrate into the reaction chamber through a substrate channel extending through an injector housing of a gas injection system, and seating the substrate on a support assembly;
injecting a precursor gas into the reaction chamber through a first series of injection ports disposed in a front face of the injector housing; and
injecting a non-precursor gas into the reaction chamber through a second series of injection ports disposed in the front face of the injector housing above the first series of injection ports,
wherein the non-precursor gas provides a gas curtain between the precursor gas and the upper inners surface of the reaction chamber thereby reducing parasitic deposition on the upper inner surface.

19. The method of claim 18, further comprising injecting an additional non-precursor gas into the reaction chamber through a third series of injection ports disposed in the front face of the injector housing below the substrate channel, wherein the additional non-precursor gas provides an additional gas curtain between the precursor gas and the lower inner surface of the reaction chamber thereby reducing parasitic deposition on the lower inner surface.

20. The method of claim 18, wherein the precursor gas comprises at least one of disilane (Si₂H₆), trisilane (Si₃H₈), tetrasilane (Si₄H₁₀), and neopentasilane (Si₅H₁₂), and the non-precursor gas comprises a halide etchant.
